(19) United States
(12) Patent Application Publication
(10) Pub. No.: US 2003/0131306 A1
(43) Pub. Date: Jul. 10, 2003

(54) Method for turbo-code block message tailing and turbo-code encoder employing the same

(76) Inventors: Yeun-Renn Ting, Taoyuan Hsien (TW); Erl-Huei Lu, Taoyuan Hsien (TW); Kuang-Shyr Wu, Taoyuan Hsien (TW); Hsien-Yu Chu, Taoyuan Hsien (TW)

Correspondence Address: J.C. Patents, Inc., Suite 250, 4 Venture, Irvine, CA, 92618, US

(21) Appl. No.: 10/034,875

(22) Filed: Dec. 27, 2001

(51) Int. Cl. H03M 13/00

(52) U.S. Cl. 714/758

(57) ABSTRACT

The present invention provides a turbo-code block message tailing method and the turbo-code encoder employing the same and having two recursive systematic convolution encoders. Each recursive systematic convolution encoder comprises M registers, counted from the input side nearest to the block message; the sequence is m₀ register, m₁, register, . . . , m_{M-1}, register. After the related data of the block message sequentially had been input, the input of the register m₀ is set and fastened to 0 by using the switch device, and sequentially outputs the data that are temporally stored in all registers, and makes the final state of all registers back to the 0 state. The present invention is applied in the short block length communication system. The error-correcting performance is manifestly excellent. Since the present invention dose not have to check the data temporally stored in the registers. Thus, the encoder structure is simple and regular.

### BACKGROUND OF THE INVENTION

1. Field of Invention

The present invention generally relates to a method and system for error control coding, and more particularly, to a turbo-code encoder and a method for the turbo-code block message tailing. Wherein, both of the encoders in the turbo-code encoder have the message tail.

2. Description of Related Art

The turbo-code is widely used in the communication system, the computer media storage system or other application system nowadays, such as the CDMA transmission system. As shown in FIG. 1 and FIG. 2, the major reason is the encoding structure of the turbo-code has two convolution code encoders having the same structure encode in parallel. Thus, the receiving end is able to decode the message repeatedly. Therefore, it provides excellent error-correcting capability. The error-correcting capability nears the Shannon limited error-correcting. FIG. 1 schematically shows a conventional turbo-code encoding structure, FIG. 2 schematically shows a conventional turbo-code decoding structure. Please be noted that the turbo-code encoding structure in FIG. 1 comprises two recursive systematic convolution encoders 110, 120 (hereafter abbreviated as RSC). Please refer to “Near Shannon limit error-correcting coding and decoding: Turbo-codes (I)”, in Proc. ICC '93, May 1993 proposed by C. Berrou, A. Glavieux and P. Thitimajshima. Since the turbo-code encoding structure mentioned above does not indicate any method for message tailing. Thus, the decoding performance is reduced because the final state of the register can not be obtained.

A conventional method for turbo-code block message tailing only provides the message tailing for the second encoder, please refer to “Performance evaluation of turbo codes for short frame transmission systems” Electronics letters, vol. 30, pp 111-112, Sept 1994 proposed by P. Jung and M. Na β han. The initial parameters of both decoders are all the same in this method. Wherein, the initial value of the forward recursion α₀(0)=1, α₀(m≠0)=0. Wherein, the subscript 0 of α₀ denotes time 0, the 0 in parentheses denotes status m=0, α₀(0)=1 means the probability of the encoder initial state at time 0 equals to 0 is 1, α₀(m≠0)=0 denotes the probability of the initial state equals to non-zero is 0. Whereas, the initial value of the backward recursion β_{N+T}(0)=1, β_{N+T}(m≠0)=0. Wherein, β_{N+T}(0)=1 denotes the probability of the encoder final state at time N+T equals to 0 is 1, β_{N+T}(m≠0)=0 denotes the probability of the final state equals to non-zero is 0. Herein, N stands for the block length; T stands for the message tail length, and also denotes the register size.

Another conventional method for turbo-code block message tailing only provides the message tailing for the first encoder, please refer to “Illuminating the structure of Code and Decoder of Parallel Concatenated Recursive Systematic (Turbo) Codes” in Proc. IEEE GLOBECOM Conf., San Francisco, Calif. pp1298-1303, DEC. 1994 proposed by Patrick Robertson. In this method, the initial parameters of the first decoder, wherein, the initial value of the forward recursion α₀(0)=1, α₀(m≠0)=0; whereas, the initial value of the backward recursion β_{N+T}(0)=1, β_{N+T}(m≠0)=0. The initial parameters of the second decoder, wherein, the initial value of the forward recursionα₀(0)=1, α₀(m≠0)=0; whereas, the initial value of the backward recursion β_{N}(m)=α_{N}(m). For all state m, herein, N stands for the block length; T stands for the message tail length.

There is also another method that does not add any message tail after the transmission of the block message is finished. This is the so called “NOTAIL” method. Please refer to “Near Optimum error correcting coding and decoding: Turbo-codes” IEEE Trans. On Commun., Vol. 44, NO. 10. PP. 1261-1271, OCT 1996 proposed by C. Berrou and A. Glavieux, and “Turbo-Code Termination Schemes and A Novel Alternative for Short Frames”. PIMRC. 96. Seventh IEEE International Symposium on Personal Indoor and Mobile Radio Communications, vol.2, Page(s): 354-358, 1996 proposed by Mark C. Reed and Steven S. Pietrobon. The initial parameters of both decoders are all the same when using this method. Wherein, the initial value of the forward recursion α₀(0)=1, α₀(m≠0)=0. Whereas, the initial value of the backward recursion β_{N}(m)=1/(2^{M}). For all state m, herein, N stands for the block length; 2^{M} stands for the summation of all states of the decoding trellis diagram.

### SUMMARY OF THE INVENTION

The present invention provides a method for turbo-code block message tailing and the turbo-code encoder employing the same. It provides better error-correcting performance when block length is medium length (N=1024) or short block length (N=256, N=64). Especially when applying in the short block length communication system, the error-correcting performance is manifestly excellent. In addition, since the present invention does not have to check the data stored in the register, the structure of the encoder is simple and regular.

The present invention provides a turbo-code encoder, receives a small block of the block message, encodes the received block message into the turbo-code and outputs it. The turbo-code encoder at least comprises two RSC encoders, each RSC encoder comprises M registers, counted from the input side nearest to the block message, the sequence is m₀ register, m₁, register, . . . , m_{M-1} register. The output of the RSC encoder at time k Cₖ is denoted as:

Cₖ=(xₖ,y₁ₖ,y₂ₖ)

xₖ=dₖ

$$\begin{matrix}{y}_{tk} = {\sum }_{i = 0}^{M} {g}_{tfi} {a}_{k - i} \\ {a}_{k} = {d}_{k} + {\sum }_{i = 1}^{M} {g}_{tbi} {a}_{k - i}\end{matrix}$$

In the equation, t denotes the number of the RSC encoder, wherein t normally can be 1 or 2,

dₖ denotes the input bit at time k,

k is from 1 to N,

N stands for the block length of the block message,

define G_{tf} is (g_{tf1}, . . . , g_{tfM}), stands for the feed-forward generator of the t^{th} RSC encoder, further defines G_{tb} is (g_{tb1}, . . . , g_{tbM}), stands for the feedback generator of the t^{th} RSC encoder. The characteristics of the turbo-code encoder according to the present invention are: after all the related data of the block message had been sequentially input into the RSC encoders, the input of the m₀ register of the RSC encoders is set and fastened to 0. And makes the feedback value of the feedback generator of the RSC encoders that is originally feedback to the input terminal of the RSC encoder divert and send to the xₖ channel of the RSC encoder. The turbo-code encoder subsequently sends out the message tail.

According to the preferred embodiment of the present invention. Wherein, the turbo-code encoder further comprises a gate to control the input of the block message. After all the data dₖ of each block message had been input, where k is 1 to N, the gate is opened to suspend the input. Moreover, the RSC encoders output the data of all M registers that still stored in the encoders and use them as the message tail. The message tail has 4 times of M bits, they are x₁,x₂,y₁ and y₂, each has M bits.

According to the preferred embodiment of the present invention. Wherein, each RSC encoder further comprises a first switch and a second switch. The output terminal of the first switch is coupled to the input of the m₀ register. The input terminal of the second switch is coupled to the feedback generator. After all the related data of the block message had been sequentially input into the RSC encoders, the output terminal of the first switch diverts and connects to the input terminal of the grounded. Thus, to make the input of the m₀ register of the RSC encoder set and fasten to 0. In addition, the input terminal of the second switch diverts and connects to the output terminal of the xₖ channel. Thus, to make the feedback value of the feedback generator of the RSC encoders that is originally feedback to the input terminal of the RSC encoder divert and send to the xₖ channel of the RSC encoder.

According to the preferred embodiment of the present invention. Wherein, the turbo-code encoder further comprises an output switch. The output switch connects to the x₁ channel in the initial state to sequentially output data x_{1,k}, where k is 1 to N+3. After N+3 clocks, the output switch connects to x₂ channel to sequentially output data X_{2,k}, where k is from N+1 to N+3.

According to the preferred embodiment of the present invention. Wherein, the initial value of the RSC encoders forward recursion α₀(0)=1, α₀(m≠0)=0. Wherein, the subscript 0 of α₀ denotes time 0, the 0 in parentheses denotes status m=0, α₀(0)==1 means the probability of the encoder initial state at time 0 equals to 0 is 1, α₀(m≠0)=0 denotes the probability of the initial state equals to non-zero is 0. Moreover, the initial value of the RSC encoders backward recursion β_{N+T}(0)=1, α_{N+T}(m≠0)=0. Wherein, β_{N+T}(0)=1 denotes the probability of the encoder final state at time N+T equals to 0 is 1, β_{N+T}(m≠0)=0 denotes the probability of the final state equals to non-zero is 0. T stands for the message tail length.

The present invention further provides a turbo-code encoder. The difference of this encoder from the turbo-code encoder mentioned above is this encoder uses the fast RSC encoder to replace the conventional RSC encoder. The output of these fast RSC encoders at time k Ck is denoted as:

Cₖ=(xₖ,y₁ₖ, y₂ₖ)

xₖ=dₖ

$$\begin{matrix}{y}_{tk} = {d}_{k} + {\sum }_{i = 1}^{M} {g}_{tdi} {a}_{k - i} \\ {G}_{1 d} ≡ 1 ‖ {\sum }_{i = 1}^{M} {g}_{1 di} = 1 ‖ {\sum }_{i = 1}^{M} ( {g}_{1 b i} + {g}_{1 f i} )\end{matrix}$$

In the equation, ∥ denotes two binary numbers are concatenated together,

t denotes the number of the fast RSC encoder, wherein t normally can be 1 or 2,

dₖ denotes the input bit at time k,

k is from 1 to N,

N stands for the block length of the block message,

define G_{td} is (g_{td1}, . . . , g_{tdM}), stands for the direct-feed-forward generator of the t^{th} fast RSC encoder, define G_{tf} is (g_{tf1}, . . . , g_{tfM}), stands for the feed-forward generator of the t^{th} fast RSC encoder, define G_{tb} is (g_{tb1}, . . . , g_{tbM}), stands for the feedback generator of the t^{th} fast RSC encoder.

A method for the turbo-code block message tailing and the turbo-code encoder employing the same according to the present invention, making the final state of the first RSC encoder and the final state of the second RSC encoder converge to the 0 state clearly, and making the initial value of the forward recursion and the initial value of the backward recursion needed for decoding is unique and a known value. Thus, it does not have to check the data temporarily stored in the register, and is able to sequentially output all the data temporarily stored in the registers. Therefore, the decoder is able to obtain the final state of the register, thus, having the excellent error-correcting performance.

### BRIEF DESCRIPTION OF THE DRAWINGS

The accompanying drawings are included to provide a further understanding of the invention, and are incorporated in and constitute a part of this specification. The drawings illustrate embodiments of the invention, and together with the description, serve to explain the principles of the invention. In the drawings,

FIG. 1 schematically shows a conventional encoding structure of the turbo-code;

FIG. 2 schematically shows a conventional decoding structure of the turbo-code;

FIG. 3 schematically shows a structure of the recursive systematic convolution encoder applied in the first RSC encoder;

FIG. 4 schematically shows a structure of the fast recursive systematic convolution encoder applied in the first RSC encoder;

FIG. 5 schematically shows a structure of the recursive systematic convolution encoder having register size M=3;

FIG. 6 schematically shows a structure of the fast recursive systematic convolution encoder having register size M=3;

FIG. 7 schematically shows the trellis diagram of the encoder having register size M=3;

FIG. 8 schematically shows the turbo-code encoder including the message tailing circuit and having register size M=3 of the preferred embodiment according to the present invention;

FIG. 9 schematically shows another fast turbo-code encoder including the message tailing circuit and having register size M=3 of the preferred embodiment according to the present invention;

FIG. 10 schematically shows the simulation result of the turbo-code encoder according to the present invention, wherein, register size M=3, block length N=1024;

FIG. 11 schematically shows the simulation result of the turbo-code encoder according to the present invention, wherein, register size M=3, block length N=256;

FIG. 12 schematically shows the simulation result of the turbo-code encoder according to the present invention, wherein, register size M=3, block length N=64.

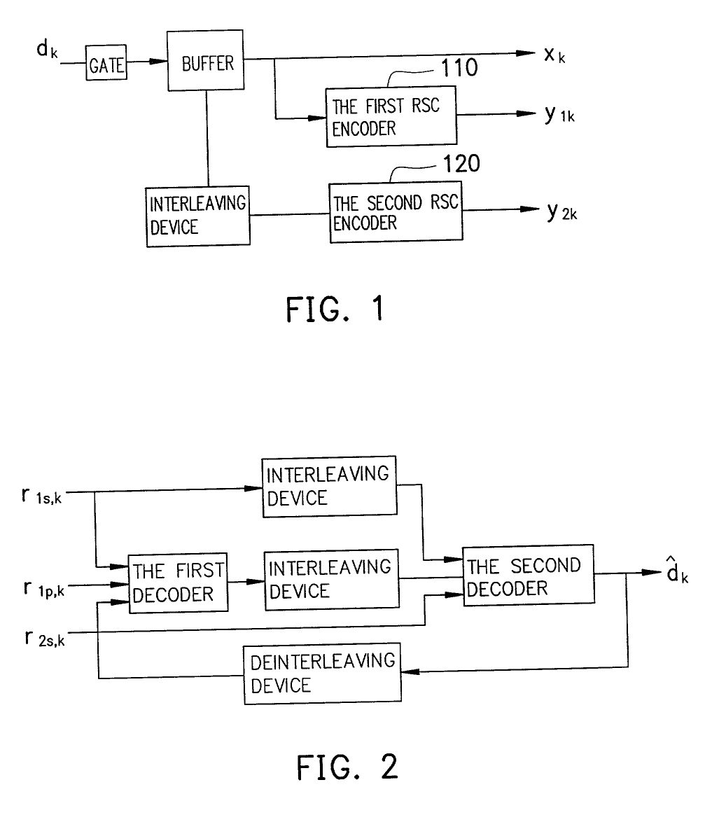

### DESCRIPTION OF THE PREFERRED EMBODIMENTS

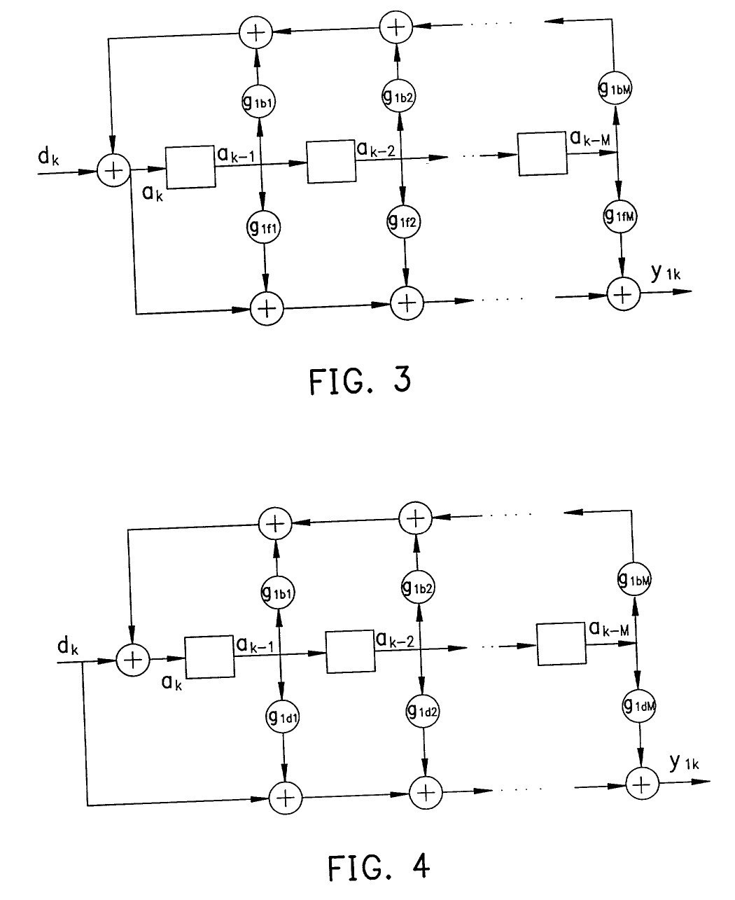

Before describing the method for turbo-code block message tailing and the turbo-code encoder employing the same according to the present invention, the RSC encoder structure must be introduced first. FIG. 3 schematically shows a structure of the recursive systematic convolution encoder applied in the first RSC encoder. Referring to FIG. 3, wherein, the sequence of input bit is denoted as d=(d₁, d₂, . . . , dₖ, . . . , d_{N}), where dₖ is the input bit of the encoder at time k, from 1 to N, and N is the block length. The output of the first encoder at time k is denoted as Cₖ=(xₖ,y₁ₖ). Since the encoder is systematic, so xₖ=dₖ. Another parity output is denoted as

$${y}_{1 k} = {\sum }_{i = 0}^{M} {g}_{1 fi} {a}_{k - i} ,$$

wherein M stands for the register size. Defining (g_{1f1}, . . . , g_{1fM}), G_{1f} is the feed-forward generator of the first encoder, the element is either 0 or 1. The equation

$${a}_{k} = {d}_{k} + {\sum }_{i = 1}^{M} {g}_{1 b i} {a}_{k - i}$$

can be obtained from the encoder. With the same reason, (g_{1b1}, . . . , g_{1bM})=G_{1b} is called as the feedback generator of the first encoder.

Another invention application corresponding to the present invention proposes a structure of the fast recursive systematic convolution encoder. Referring to FIG. 4, FIG. 4 schematically shows a structure of the fast recursive systematic convolution encoder applied in the first RSC encoder. Wherein, defining:

$${G}_{1 d} ≡ 1 ‖ {\sum }_{i = 1}^{M} {g}_{1 di} = 1 ‖ {\sum }_{i = 1}^{M} ( {g}_{1 b i} + {g}_{1 f i} )$$

as the direct-feed-forward generator parameter of the first encoder, wherein, represents two binary numbers concatenated together, such as 1∥001=1001.

Considering the state of the binary RSC code having register size equal to M at time k is Sₖ, so Sₖ=(aₖ, aₖ₋₁, . . . , a_{k-M+1}). It is assumed the initial state of the encoder is the 0 state, that is, S₀=(0,0 , . . . , 0)=0. In the general convolution code structure, as long as M units of 0 are input at the last, the final state is converged to the 0 state. However, since the RSC encoder is recursive, simply input M units of 0 can not make the final state converged to the 0 state.

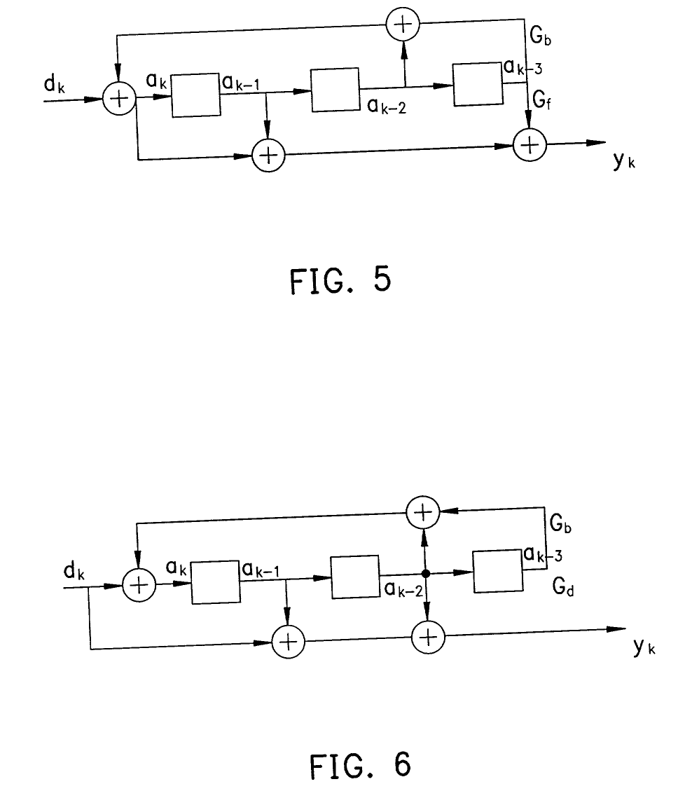

For easy to describe, the turbo-code of the third generation CDMA mobile communication standard is exemplified here. Referring to FIG. 5, FIG. 5 schematically shows a structure of the recursive systematic convolution encoder having register size M=3. Wherein, the register size of the first RSC encoder M=3, and the second encoder is the same as the first encoder. So, g_{1bi}=g_{2bi}≡g_{bi} and g_{1fi}=g_{2fi}≡g_{fi}. Wherein, the code ratio R=⅓, the feedback generator parameter and the feed-forward generator parameter is G_{b}=1011, G_{f}=1101 respectively. Please refer to FIG. 6 for using (equal) fast RSC encoder structure. FIG. 6 schematically shows a structure of the fast recursive systematic convolution encoder having register size M=3. The feedback generator parameter and the direct-feed-forward generator parameter is G_{b}=1011, G_{d}=1110 respectively.

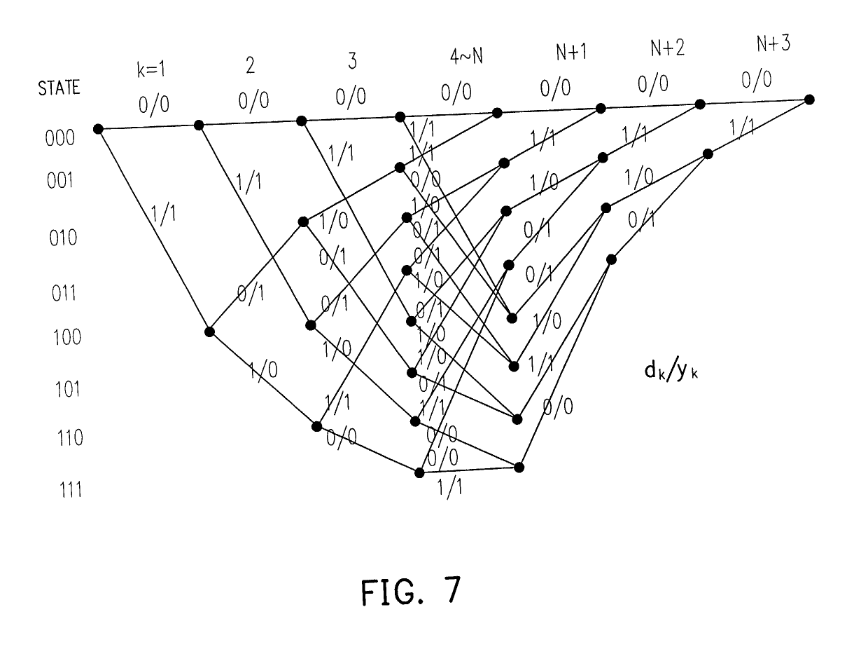

FIG. 7 schematically shows the trellis diagram having register size M=3. Referring to FIG. 7, it is known that the possible conditions that make the final state converge to the 0 state at message tailing are as follows:

| Time point: | N | | N + 1 | | N + 2 | | N + 3 |
|---|---|---|---|---|---|---|---|
| State: | (0,0,0)⁰ | → | (0,0,0)⁰ | → | (0,0,0)⁰ | → | (0,0,0) |
| | (0,0,1)¹ | → | (0,0,0)⁰ | → | (0,0,0)⁰ | → | (0,0,0) |
| | (0,1,0)¹ | → | (0,0,1)¹ | → | (0,0,0)⁰ | → | (0,0,0) |
| | (0,1,1)⁰ | → | (0,0,1)¹ | → | (0,0,0)⁰ | → | (0,0,0) |
| | (1,0,0)⁰ | → | (0,1,0)¹ | → | (0,0,1)¹ | → | (0,0,0) |
| | (1,0,1)¹ | → | (0,1,0)¹ | → | (0,0,1)¹ | → | (0,0,0) |
| | (1,1,0)¹ | → | (0,1,1)⁰ | → | (0,0,1)¹ | → | (0,0,0) |
| | (1,1,1)⁰ | → | (0,1,1)⁰ | → | (0,0,1)¹ | → | (0,0,0) |

Wherein, (x,x,x)¹ denotes Sₖ=(aₖ,aₖ₋₁,aₖ₋₂) binary state, k is from N to N+3, i is the input value that makes Sₖ₊₃ back to the 0 state, and N is a block length. One of the major marrows of the method of turbo-code block message tailing according to the present invention is outputting the data still stored in the registers to use as the message tail, and makes the final state converge to the 0 state. Wherein, the message tail has 4 times of M bits, they are x₁,x₂,y₁ and Y₂ each has M bits.

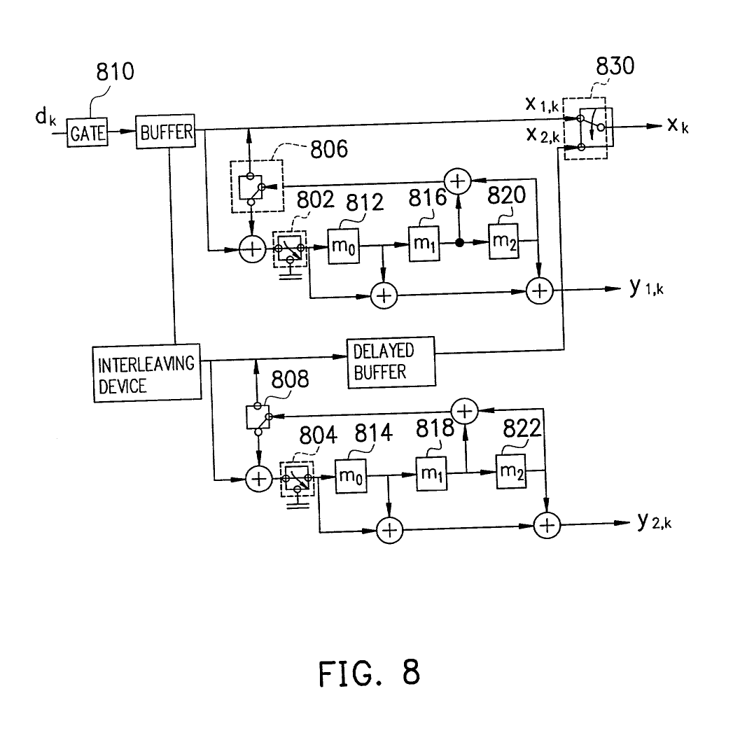

FIG. 8 schematically shows the turbo-code encoder including the message tailing circuit and having register size M=3 of the preferred embodiment according to the present invention. Referring to FIG. 8, the turbo-code encoder of the embodiment is composed of two RSC encoders in parallel. After all block data dₖ had been input, k is from 1 to N, the gate 810 is opened to suspend the input. After all block messages had been input into these two RSC encoders, the output terminal of the switch 802 and the switch 804 diverts and connects to the input terminal of the grounded. Since the output terminal of the switch 802 and the switch 804 is coupled to the input terminal of the m₀ register 812, 814, thus, the input of the m₀ register 812, 814 of these two RSC encoders is fastened to 0. The input terminal of the switch 806 diverts and connects to the output terminal of the x₁ channel. Moreover, the input terminal of the switch 808 also diverts and connects to the output terminal of the x₂ channel. Therefore, no matter SN is in which state, after 3 clocks, the final register state by all means equals to (0,0,0). Since the output terminal of the switch 802 and the switch 804 diverts and connects to the input terminal of the grounded, the input of the m₀ register 812, 814 by all means equals to 0. In addition, the data stored in m₀ register 812, m₁ register 816, m₂ register 820 are sequentially output from x₁ channel and y₁ channel. Whereas, the data stored in m₀ register 814, m₁ register 818, m₂ register 822 are sequentially output from x₂ channel and y2 channel.

The switch 830 connects to x₁ channel in the initial state, sequentially outputs data x_{1,k}, where k is from 1 to N+3, after N+3 clocks, the switch 830 connects to x₂ channel, sequentially outputs data X_{2,k}, where k is from N+1 to N+3. The message tailing method makes the final state of the first RSC encoder and the second RSC encoder all converge to the 0 state. In other words, the parameter initial state and the parameter final state needed for the first decoder and the second decoder in the receiving side are all the known values. The initial value of the forward recursion α₀(0)=1, α₀(m≠0)=0. Wherein, the subscript 0 of α₀ denotes time 0, the 0 in parentheses denotes status m=0, α₀(0)=1 means the probability of the encoder initial state at time 0 equals to 0 is 1, α₀(m≠0)=0 denotes the probability of the initial state equals to non-zero is 0. Whereas, the initial value of the backward recursion β_{N+T}(0)=1, β_{N+T}(m≠0)=0. Wherein, β_{N+T}(0)=1 denotes the probability of the encoder final state at time N+T equals to 0 is 1, β_{N+T}(m≠0)=0 denotes the probability of the final state equals to non-zero is 0. T stands for the message tail length. The message tailing method proposed by the present invention clearly makes the final state of the first RSC encoder and the final state of the second RSC encoder converge to the 0 state, and both the initial value of the forward recursion and the initial value of the backward recursion needed for decoding are all the known values. Thus, the method of the present invention can be called as the dual encoder message tailing method.

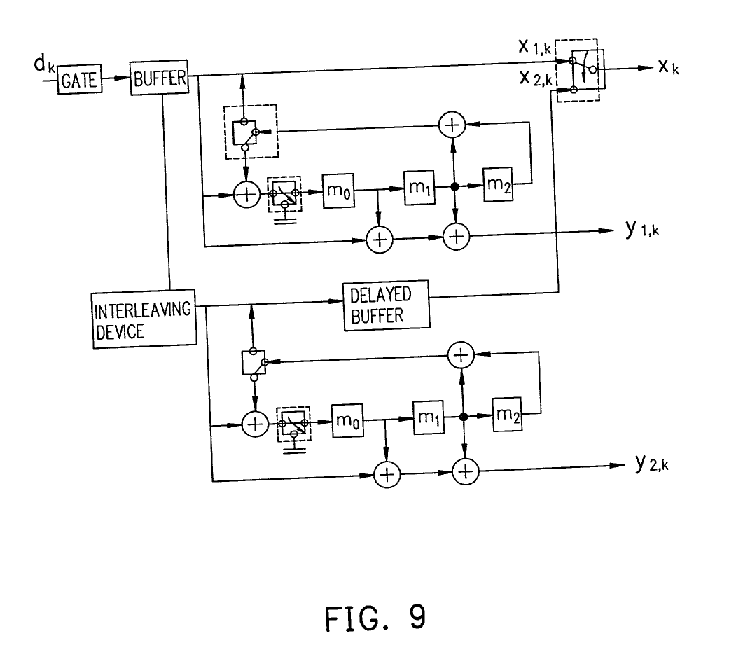

FIG. 9 schematically shows another fast turbo-code encoder including the message tailing circuit and having register size M=3 of the preferred embodiment according to the present invention. The major difference between FIG. 9 and FIG. 8 is the fast turbo-code encoder is used in FIG. 9 to replace the conventional turbo-code encoder. Those who skilled in the related arts should understand the operation method of FIG. 9 by referring to FIG. 8, here will not say more than is needed.

Although the embodiment mentioned above uses the turbo-code encoder having register size M=3 to explain the operation of the message tailing circuit. Those who skilled in the related arts can readily deduct other turbo-code encoder having different number of the register size M, as long as the marrow of the turbo-code block message tailing method of the present invention is grasped. When the related data of the block message are sequentially input into these RSC encoders, the turbo-code encoder encodes and outputs normally. After all the related data of the block message had been sequentially input into the RSC encoders, the RSC sequentially outputs the data stored in M registers, and makes the final state of these M registers back to the 0 state. This is major accomplished by setting and fastening the input value of the m₀ register of the RSC encoder to 0, and by making the feedback value of the feedback generator of the RSC encoders that is originally feedback to the input terminal of the RSC encoder divert and send to the xₖ output channel of the RSC encoder. The turbo-code encoder subsequently sends out the message tail. Wherein, the message tail has 4 times of M bits, they are X₁,X₂,y₁ and y₂, each has M bits. The output of the turbo-code encoder connects to the x₁ channel of the first RSC encoder in the initial state to sequentially output data x_{1,k}, where k is 1 to N+M. After N+M clocks, the output of the turbo-code encoder connects to the x₂ channel of the second RSC encoder to sequentially output data x_{2,k}, where k is from N+1 to N+M.

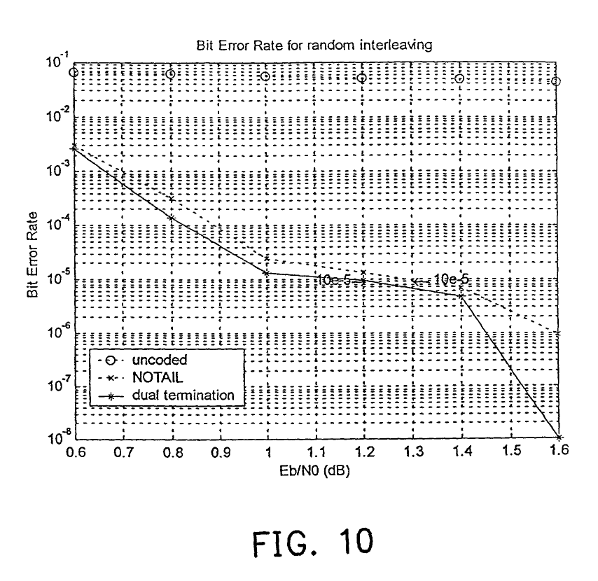

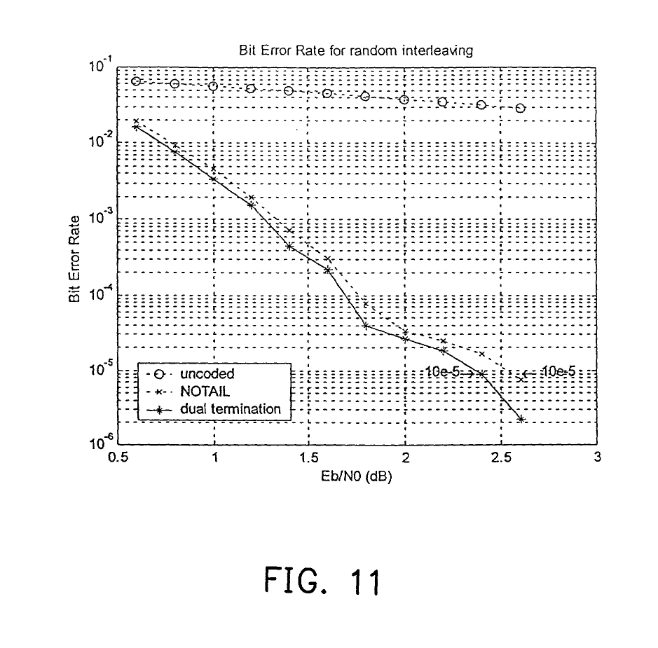

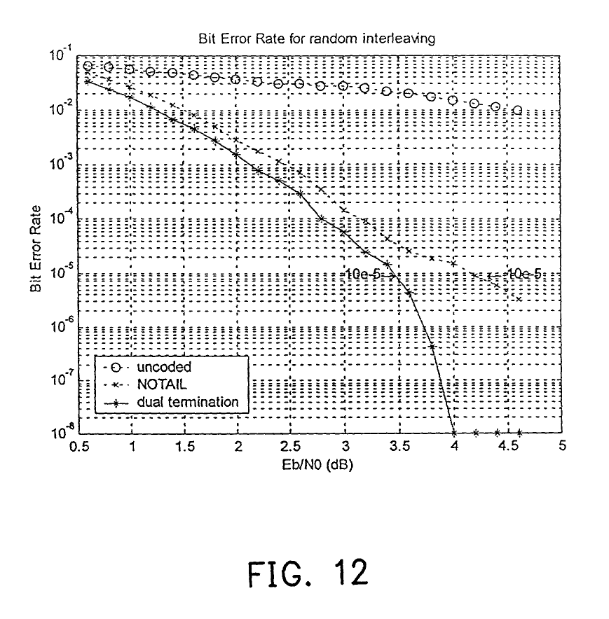

It is known for those who skilled in the related arts that the NOTAIL method is better than other conventional methods in many signal/noise ratio (SNR) intervals. Therefore, the present invention compares the dual encoder message tailing method and the NOTAIL method hereafter. In order to prevent from having too long latency for decoding, the medium or short block length are chosen, they are N=1024, 256 and 64 respectively. Further choosing register size all equal to 3, the code ratio R=⅓, the feedback generator and the feed-forward generator is G_{f}=1101,G_{d}=1110 respectively, the iterative decoding times is 6 times. The random interleaving method is adopted between the first RSC encoder and the second RSC encoder. The simulation results obtained are shown in FIG. 10, FIG. 11 and FIG. 12. They are N=1024, 256 and 64 with different size of block length respectively. The vertical axis in these three diagrams is the decoding performance represented by the bits error rate (BER), the horizontal axis is the communication environment represented by the signal/noise ratio (SNR). As we can see from the diagrams, under the same SNR situation, the bigger the N, the better the decoding performance, this is accorded with the theory.

FIG. 10 schematically shows the simulation result of the turbo-code encoder according to the present invention, wherein, register size M=3, block length N=1024. It is known from FIG. 10, the dual encoder message tailing method of the present invention is better than the NOTAIL method. The decoding performance improves about 0.1 dB in BER is 10⁻⁵. Furthermore, in order to prevent having too long decoding latency, N should not be to long. FIG. 11 schematically shows the simulation result of the turbo-code encoder according to the present invention, wherein, register size M=3, block length N=256. It is known from FIG. 11, the decoding performance improves about 0.2 dB in BER is 10⁻⁵. The other N that is smaller than this should be chosen. FIG. 12 schematically shows the simulation result of the turbo-code encoder according to the present invention, wherein, register size M=3, block length N=64. It is known from FIG. 12, the decoding performance improvement of the dual encoder message tailing method according to the present invention is further manifest. The decoding performance improves about 0.8 dB in BER is 10⁻⁵.

A turbo-code block message tailing method and the turbo-code encoder employing the same according to the present invention, at least have following advantages:

1. Clearly makes the final state of the first RSC encoder and the final state of the second RSC encoder all converge to the 0 state, and makes the initial value of the backward recursion needed for decoding to be unique and a known value.

2. Through the observation of the simulation results, no matter the block length is medium or short length, the decoding performance of the dual encoder message tailing method is better than others'. The shorter the block length, the bigger the performance improve. Therefore, it is best suitable for the CDMA mobile communication system that can not tolerate the long decoding latency.

Although the invention has been described with reference to a particular embodiment thereof, it will be apparent to one of the ordinary skill in the art that modifications to the described embodiment may be made without departing from the spirit of the invention. Accordingly, the scope of the invention will be defined by the attached claims not by the above detailed description.

What is claimed is:

1. A turbo-code encoder, receiving and encoding a block message, the turbo-code encoder at least comprising:
two RSC encoders, each one of the RSC encoders comprising M registers, counted from the input side nearest to the block message, wherein the sequence is m₀ register, m₁ register, . . . , m_{M-1} register, the output of the RSC encoders at time k Cₖ is denoted as:
Cₖ=(xₖ,y₁ₖ, y₂ₖ)
xₖ=dₖ
$$\begin{matrix}{y}_{tk} = {\sum }_{i = 0}^{M} {g}_{tfi} {a}_{k - i} \\ {a}_{k} = {d}_{k} + {\sum }_{i = 1}^{M} {g}_{tbi} {a}_{k - i} ,\end{matrix}$$
where t denotes the number of the RSC encoder, wherein t can be 1 or 2,
dₖ denotes the input bit at time k,
k is from 1 to N, and
N stands for the block length of the block message;
defining G_{tf} is (g_{tf}, . . . , g_{tfM}), stands for the feed-forward generator of the t^{th} RSC encoder;
further defining G_{tb} is (g_{tb1}, . . . , g_{tbM}), stands for the feedback generator of the t^{th} RSC encoder, the characteristics of the turbo-code encoder are:
after all the related data of the block message have been sequentially input into the RSC encoders, the input of the m₀ register of the RSC encoders is set and fastened to 0, and makes the feedback value of the feedback generator of the RSC encoders that is originally feedback to the input terminal of the RSC encoders is then sent to the xₖ channel of the RSC encoders, the turbo-code encoder subsequently sends out a message tail.

2. The turbo-code encoder of claim 1, further comprising a gate, wherein after all the data dₖ of each block message have been input, where k is 1 to N, the gate is opened to suspend the input, the RSC encoders output the data of all M registers that still stored in the encoders and used them as the message tail, the message tail has 4 times of M bits, wherein x₁,x₂,y₁ and Y₂, each has M bits.

3. The turbo-code decoder of claim 1, wherein each RSC encoder further comprises a first switch and a second switch, the output terminal of the first switch is coupled to the input of the m₀ register, the input terminal of the second switch is coupled to the feedback generator, after all the related data of the block message had been sequentially input into the RSC encoders, the output terminal of the first switch diverts and connects to the input terminal of the grounded to make the input of the m₀ register of the RSC encoders set and fasten to 0; the input terminal of the second switch diverts and connects to the output terminal of the xₖ channel, to make the feedback value of the feedback generator of the RSC encoders that is originally feedback to the input terminal of the RSC encoders divert and send to the xₖ channel of the RSC encoders.

4. The turbo-code decoder of claim 1, further comprising an output switch, wherein the output switch connects to the x, channel in the initial state to sequentially output data x_{1,k}, where k is 1 to N+3, after N+3 clocks, the output switch connects to x₂ channel to sequentially output data x_{2,k}, where k is from N+1 to N+3.

5. The turbo-code decoder of claim 1, wherein the initial value of the RSC encoders forward recursion is set as α₀(0)=1, α₀(m≠0)=0, where the subscript 0 of ₀ denotes time 0, the 0 in parentheses denotes status m=0, α₀(0)=1 means that the probability of the encoder initial state at time 0 equals to 0 is 1, and α₀(m≠0)=0 denotes that the probability of the initial state equals to non-zero is 0.

6. The turbo-code decoder of claim 1, wherein the initial value of the RSC encoders backward recursion β_{N+T}(0)=1, β_{N+T}(m≠0)=0, wherein, β_{N+T}(0)=1 denotes the probability of the encoder final state at time N+T equals to 0 is 1, β_{N+T}(m≠0)=0 denotes the probability of the final state equals to non-zero is 0, T stands for the message tail length.

7. A turbo-code encoder, receiving and encoding a block message, the turbo-code encoder at least comprising:
two fast RSC encoders, each one of the fast RSC encoders comprising M registers, counted from the input side nearest to the block message, wherein the sequence is m₀ register, m₁ register, . . . , m_{M-1} register, the output of the fast RSC encoders at time k Cₖ is denoted as:
Cₖ=(xₖ,y₁ₖ,y₂ₖ)
xₖ=dₖ
$$\begin{matrix}{y}_{tk} = {d}_{k} + {\sum }_{i = 1}^{M} {g}_{tdi} {a}_{k - i} \\ {G}_{1 d} ≡ 1 ‖ {\sum }_{i = 1}^{M} {g}_{1 di} = 1 ‖ {\sum }_{i = 1}^{M} ( {g}_{1 b i} + {g}_{1 f i} ) ,\end{matrix}$$
where ∥ denotes two binary numbers are concatenated together,
t denotes the number of the fast RSC encoder, wherein t can be 1 or 2,
dₖ denotes the input bit at time k,
k is from 1 to N,
N stands for the block length of the block message;
defining G_{td} is (g_{td1}, . . . , g_{tdM}), stands for the direct-feed-forward generator of the t^{th} fast RSC encoder;
defining G_{tf} is (g_{tf1}, . . . , g_{tfM}), stands for the feed-forward generator of the t^{th} fast RSC encoder;
defining G_{tb} is (g_{tb1}, . . . , g_{tbM}), stands for the feedback generator of the t^{th} fast RSC encoder, the characteristics of the turbo-code encoder are:
after all the related data of the block message had been sequentially input into the fast RSC encoders, the input of the m₀ register of the fast RSC encoders are set and fastened to 0, and the feedback value of the feedback generator of the fast RSC encoders that is originally feedback to the input terminal of the fast RSC encoders is then sent to the xₖ channel of the fast RSC encoders, and the turbo-code encoder subsequently sends a message tail out.

8. The turbo-code decoder of claim 7, further comprising a gate, wherein after all the data dₖ of each block message had been input, where k is 1 to N, the gate is opened to suspend the input, the fast RSC encoders output the data of all M registers that still stored in the encoders and used them as the message tail, the message tail has 4 times of M bits, they are x₁,x₂,y₁ and y₂, each has M bits.

9. The turbo-code decoder of claim 7, wherein each one of the fast RSC encoders further comprises a first switch and a second switch, wherein the output terminal of the first switch is coupled to the input of the m₀ register, and the input terminal of the second switch is coupled to the feedback generator, wherein after all the related data of the block message had been sequentially input into the fast RSC encoders, the output terminal of the first switch diverts and connects to the input terminal of the grounded to make the input of the m₀ register of the fast RSC encoders set and fasten to 0; the input terminal of the second switch diverts and connects to the output terminal of the xₖ channel, to make the feedback value of the feedback generator of the fast RSC encoders that is originally feedback to the input terminal of the fast RSC encoders divert and send to the xₖ channel of the fast RSC encoders.

10. The turbo-code decoder of claim 7, further comprising an output switch, wherein the output switch connects to the x₁ channel in the initial state to sequentially output data x_{1,k}, where k is 1 to N+3, after N+3 clocks, the output switch connects to x₂ channel to sequentially output data x_{2,k}, where k is from N+1 to N+3.

11. The turbo-code decoder of claim 7, wherein the initial value of the fast RSC encoders forward recursion is set to be α₀(0)=1, α₀(m≠0)=0, wherein the subscript 0 of 0 denotes time 0, the 0 in parentheses denotes status m=0, α₀(0)=1 means the probability of the encoder initial state at time 0 equals to 0 is 1, α₀(m≠0)=0 denotes the probability of the initial state equals to non-zero is 0.

12. The turbo-code decoder of claim 7, wherein the initial value of the fast RSC encoders backward recursion is set to be β_{N+T}(⁰)=1, β_{N+T}(m≠0)=0, wherein, β_{N+T}(0)=1 denotes the probability of the encoder final state at time N+T equals to 0 is 1, β_{N+T}(m≠0)=0 denotes the probability of the final state equals to non-zero is 0, T stands for the message tail length.

13. A turbo-code block message tailing method, applying in a turbo-code encoder, receiving and encoding a block message, wherein the turbo-code encoder at least comprises two RSC encoders, each RSC encoder comprises M registers, counted from the input side nearest to the block message, the sequence is m₀ register, m₁ register, . . . , m_{M-1} register, the turbo-code block message tailing method comprising the steps of:
when the related data of the block message are sequentially input into the RSC encoders, the turbo-code encoder encoding and outputting; and
after all the related data of the block message have been sequentially input into the RSC encoders:
sequentially outputting the data temporally stored in the M registers; and
making the final state of the M registers all back to the 0 state.

14. The turbo-code block message tailing method of claim 13, wherein each one of the RSC encoders further comprises a feedback generator, after all the related data of the block message have been sequentially input into the RSC encoders, further comprising:
making the input of the m₀ register of the RSC encoders set and fasten to 0;
making the feedback value of the feedback generator of the RSC encoders that is originally feedback to the input terminal of the RSC encoders divert and send to the xₖ channel of the RSC encoders, and the turbo-code encoder subsequently sending a message tail out.

15. The turbo-code block message tailing method of claim 14, wherein the output of the turbo-code encoder connects to the x₁ channel of a first RSC encoder in the initial state to sequentially output data x_{1,k}, where k is 1 to N+M, after N+M clocks; the output of the turbo-code encoder connects to the x₂ channel of the second RSC encoder to sequentially output data x₂,k, where k is from N+1 to N+M, and N stands for the block length of the block message.

16. The turbo-code block message tailing method of claim 14, wherein after all the data dₖ of each block message have been input, where k is 1 to N, the input is suspended, the RSC encoders output the data of all M registers that still stored in the encoders and use them as the message tail, the message tail has 4 times of M bits, wherein x₁,x₂,y₁ and y₂, each has M bits.
